(19) United States
(12) Patent Application Publication
(10) Pub. No.: US 2015/0345010 A1
(43) Pub. Date: Dec. 3, 2015

(54) METHODS OF MAGNETICALLY ENHANCED PHYSICAL VAPOR DEPOSITION

(71) Applicants: Christopher Muratore, Dayton, OH (US); John Bultman, Huber Heights, OH (US); Andrey A. Voevodin, Dayton, OH (US); Jianjun Hu, Beavercreek, OH (US)

(72) Inventors: Christopher Muratore, Dayton, OH (US); John Bultman, Huber Heights, OH (US); Andrey A. Voevodin, Dayton, OH (US); Jianjun Hu, Beavercreek, OH (US)

(73) Assignees: University of Dayton, Dayton, OH (US); Government of the United States, as Represented by the Secretary of the Air Force, Wright-Patterson AFB, OH (US)

(21) Appl. No.: 14/501,994

(22) Filed: Sep. 30, 2014

Related U.S. Application Data
(60) Provisional application No. 61/884,203, filed on Sep. 30, 2013.

(51) Int. Cl. C23C 14/35; C23C 14/34; C23C 14/06; C23C 14/22

(52) U.S. Cl. CPC C23C 14/35; C23C 14/228; C23C 14/3435; C23C 14/0623

(57) ABSTRACT

Methods for magnetically enhanced physical vapor deposition are disclosed. The methods include providing a magnetically enhanced vapor deposition device defining a vapor deposition chamber, having a magnetic field source proximate a magnetron target that is positioned within the vapor deposition chamber and coupled to a power source, and having a substrate holder positioned within the vapor deposition chamber, placing a substrate in the substrate holder, activating the magnetic field source to provide a magnetic field that controls a charged particle flux within the physical vapor deposition chamber, and activating the power source thereby depositing a few-layer film of the material comprising the magnetron target onto the substrate. The few-layer film may be a transition metal dichalcogenide, such as MoS₂.

### RELATED APPLICATIONS

This application claims the benefit of U.S. Provisional Application 61/884,203, filed Sep. 30, 2013.

### STATEMENT REGARDING FEDERALLY SPONSORED RESEARCH OR DEVELOPMENT

This invention was made with U.S. Government support under the Air Force, AFRL/PKMN, Wright-Patterson Air Force Base, Grant No. FA8650-11-D-5401-0011. The U.S. Government may have certain rights in the invention.

### TECHNICAL FIELD

The present application relates generally to methods of magnetically enhanced physical vapor deposition, more particularly, to methods of growing continuous, few-layer transition metal dichalcogenides (“TMDs”) over large areas using the magnetically enhanced physical vapor deposition.

### BACKGROUND

Molybdenum disulfide, MoS₂, is a naturally abundant transition metal dichalcogenide material with a layered atomic structure used in bulk form for diverse technological applications for decades due to its remarkable mechanical (e.g., low shear strength) and catalytic (e.g., hydrosulfurization) performance. Transition metal dichalcogenides such as MoS₂ have also been examined for use in solar cells and photocatalytic applications due to their indirect band gap at a convenient energy of ˜1 eV. Recently, measurements of few-layer MoS₂ have demonstrated desirable characteristics for electronic materials such as a direct band gap of ˜2 eV, high on/off ratios (>10¹⁰), and capacity to handle high current densities. These characteristics make MoS₂ and other few-layer TMDs strong candidate materials for low power transistors. Additional studies revealed electroluminescence and sensitivity of electrical resistance to adsorbed molecules for sensing applications. The direct band gap coupled with reduced thickness (for transparency and flexibility) also suggests potential applications in optoelectronics, such as photodetectors, photovoltaics, and electroluminescent devices.

Most few-layer TMD materials have been produced by exfoliation from a bulk crystal, possessing a lack of scalability for device production and limited experimental opportunities to examine device performance due to geometry and low device yield. Such exfoliation techniques are not suitable because throughput is low and uniformity is poor over areas larger than approximately 100 microns. Recent reports show few-layer MoS₂ materials grown on electrically insulating surfaces by chemical vapor deposition (CVD). These films appear to be composed of isolated flakes with a characteristic length of approximately 5 nm, separated by amorphous material or voids with gaps of approximately the same size, which results in high electrical resistivity over large areas due to inter-flake resistance. While current results from CVD experiments are a step in the right direction towards device-scale production of few-layer TMD materials for electronics, control of the number of TMD layers formed or deposited over a broad surface area, not as flakes or isolated islands, is yet to be reported for any synthesis process.

### SUMMARY

Methods for magnetically enhanced physical vapor deposition and substrates having a few-layer film deposited thereon made according to the methods are disclosed. The methods include providing a magnetically enhanced vapor deposition device defining a vapor deposition chamber, having a magnetic field source proximate a magnetron target that is positioned within the vapor deposition chamber and coupled to a power source, and having a substrate holder positioned within the vapor deposition chamber, placing a substrate, such as silicon dioxide, highly oriented graphite, polycrystalline metal, or a polymer that is chemically stable in the vapor deposition chamber during the method, in the substrate holder, activating the magnetic field source to provide a magnetic field that controls a charged particle flux within the physical vapor deposition chamber, and activating the power source thereby depositing a few-layer film of the material comprising the magnetron target onto the substrate. The methods may also include the addition of a heat source to the magnetically enhanced vapor deposition device. The heat source is coupled to the substrate holder to transfer heat thereto and the methods include activating the heat source. In one embodiment, the heat source heats the substrate holder and hence the substrate to at least 200° C. Also, the method may include applying vacuum to the vapor deposition chamber and, subsequently, backfilling the vapor deposition chamber with an inert gas, a reactive gas, or a combination thereof. When a reactive gas is present, the magnetron target 108 may be a transition metal that reacts with the reactive gas to form a dichalcogenide.

In one embodiment of the methods, the magnetron target include a source of a transition metal dichalcogenide that may be a bulk material having the same composition as the few-layer film desired for deposition on the substrate. In one embodiment, the transition metal dichalcogenide includes molybdenum sulfide (MoS₂), which may comprise uniform and/or continuous layers of MoS₂ that may cover a surface area of at least 1 cm² or at least 2 cm².

In one embodiment, the magnetic field source is an adjustable magnetic field source, for example a Helmholtz coil. In another embodiment, the magnetic field source is a permanent magnet. In either case, the magnetic field created thereby is directed parallel or has a generally parallel component relative to a primary surface of the magnetron target and is at least strong enough to guide electrons present in the vapor deposition chamber.

In one embodiment, the power source is a modulated power source that operates in a frequency range of about 50 to about 85 kHz and a reverse time of about 0.4 to about 4 microseconds with a power density >1 Wcm⁻².

### BRIEF DESCRIPTION OF THE DRAWINGS

FIG. 1A is a schematic representation of a physical vapor deposition device for use in the disclosed methods.

FIG. 1B is example of photographs of magnetron plasma particle flux during the device depicted in FIG. 1A operation without (left) and with (right) magnetic field application with the Helmholtz coil energizing.

FIG. 2A is a cross-sectional view, transmission electron micrograph (“TEM”) of a 5-layer MoS₂ film on a SiO₂ substrate. In the TEM each white line corresponds to a molecular layer of MoS₂.

FIG. 2B is a structural schematic of the atomic layer composition of the MoS₂ film of FIG. 2A.

FIG. 3 is a Raman spectra and thickness-dependent photoluminescence spectra for two samples of MoS₂ made by the method disclosed herein.

### DETAILED DESCRIPTION

The following detailed description will illustrate the general principles of the invention, examples of which are additionally illustrated in the accompanying drawings. In the drawings, like reference numbers indicate identical or functionally similar elements.

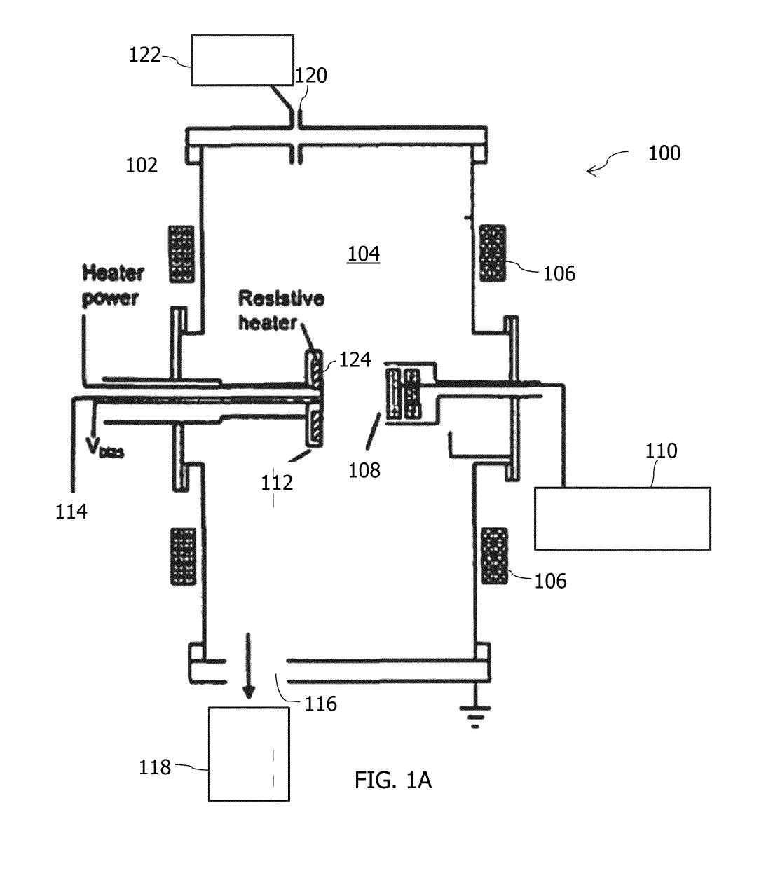

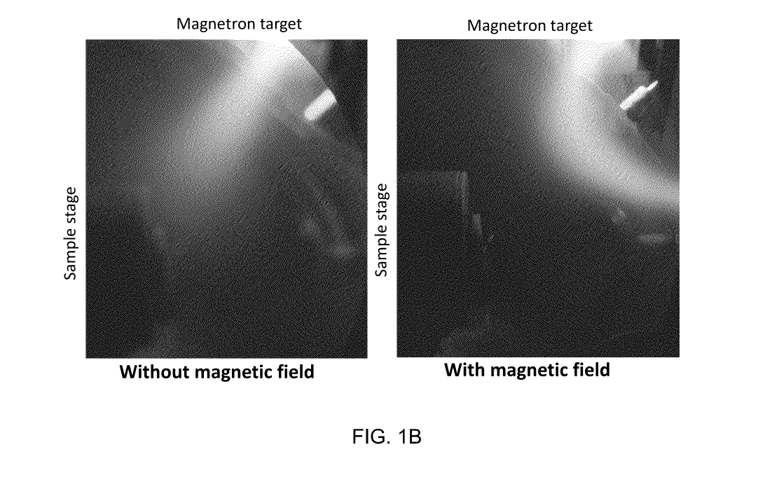

FIG. 1A is an illustration of a magnetically enhanced vapor deposition device, generally designated by reference numeral 100, for use in the methods disclosed herein. The device 100 includes a housing 102 defining a physical vapor deposition chamber 104. The device 100 includes a magnetic field source 106 proximate a magnetron target or plasma source 108 that is coupled to a power source 110, such as a dc or modulated power source, and a substrate holder 112 that is coupled to a heat source 114 (resistive as included in FIG. 1A or radiative (not shown)), and may include a port 116 connected to a vacuum pump 118 and a port 120 connected to a processing gas source 122. The processing gas source 122 may include an inert gas (such as argon), a reactive gas (such as hydrogen sulfide), or a combination thereof. While the illustrated embodiment includes separate ports 116, 120 for connection to the vacuum pump 118 and the processing gas source 122, the device 100 could include a single port coupled to both the vacuum pump and the processing gas source(s) that includes a T-, Y-, or similar connection having a valve controlling the flow through the single port.

The magnetic field source 106 applies a magnetic field in the range of about 1- to about 1000 Gauss between the magnetron plasma source 108 and the substrate to guide the particle flux (may include ions and electrons) within the physical vapor deposition chamber 104 and enables control of the particle flux incident upon a substrate held in the substrate holder 112.

FIG. 1B compares photographs taking during operation of the magnetically enhanced vapor deposition device without (the left image) and with (the right image) the activation of the magnetic field source. The magnetic field source 106 also enables control of electric fields which are related to the plasma density within the physical vapor deposition chamber 104. In one embodiment, the magnetic field is directed parallel or with a significant parallel component relative to a primary surface 124 of the magnetron target 108 (or sputtering source). The strength of the magnetic field is such that it does not significantly affect the flux of neutral atoms to the substrate. The electrons and ions in the plasma volume, which are composed of a fraction of processing gas ions (e.g., Ar⁺) and ionized atoms liberated from the sputter target surface, can be steered into or away from the substrate by this magnetic field. The magnetic field only needs to be strong enough to guide the electrons, as the ions require a much larger magnetic field for direct guidance, but will “follow” the electrons to maintain electrical neutrality of the plasma, and thus ions can be guided indirectly with much lower magnetic field strengths. The strength of the field can be adjusted by adjusting the magnetic field source 106. In one embodiment, the magnetic field source 106 may be a set of Helmholtz coils, or any configuration of current passing through wire that generates a magnetic field, which may be adjustable by changing the electrical current applied thereto. In another embodiment, the magnetic field source 106 may be comprised of permanent magnets, which may be substituted with an alternate permanent magnet of different characteristics inside and outside of the volume of the physical vapor deposition chamber 104.

The modulated power source 110 applies modulated power to the magnetron target or targets (plasma source) in a range of average power densities over 1 Wcm⁻². The modulated power source 110 can be operated in dc mode or modulated in terms of frequency and duty factor. The power supply can be used from about 5 to about 350 kHz. Well aligned, few-layer transition metal dichalcogenide films, however, were most prevalent at about 50 to about 85 kHz, and reverse time of less than 2 microseconds. The pulse characteristics in mid-frequency pulsed dc sputtering have been shown to affect the atomic structure of thicker transition metal dichalcogenide films by controlling the density of ions generated and by modulating the flux of neutral species to the surface. These characteristics are also shown to have strong impact on few-layer TMD materials. Such power may be applied to one plasma source fitted with a target of the desired TMD material or multiple sources.

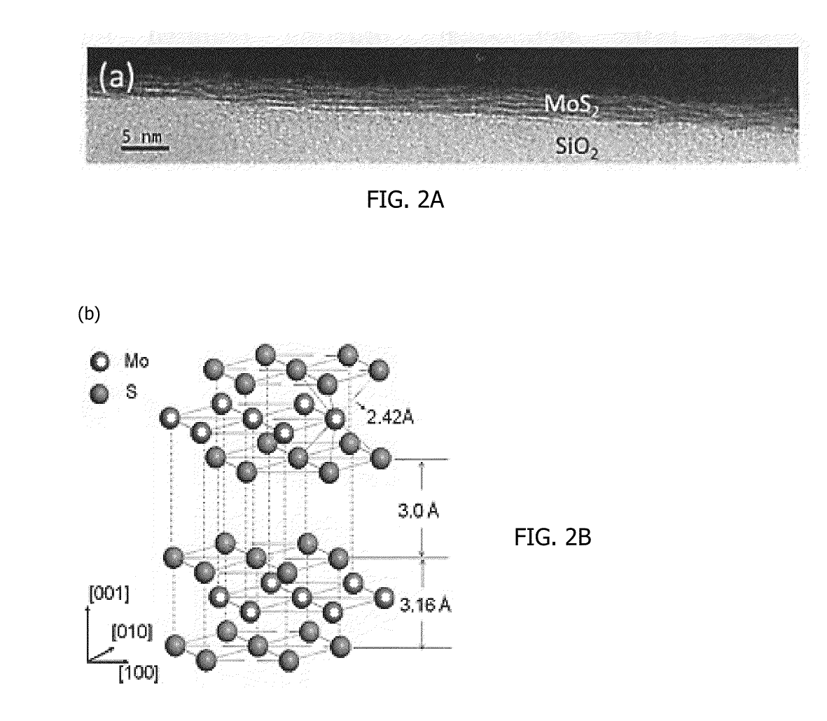

The temperature of the substrate during growth also plays a role in the atomic structure of the materials. Few-layer films are observed at about 200° C., with increased crystalline domain size as temperature increases to about 700° C. Growth substrates may be silicon oxide, as shown in FIG. 2A, highly oriented graphite, polycrystalline metals, or other surfaces such as flexible polymers or other 2D materials such as graphene.

The control of the magnetic field source 106 and the modulation control of the modulated power source 110 together produce well-ordered TMDs of 1 or more monolayer, but typically having an upper limit of about 30 to about 50 molecular layers. Beyond this thickness (or number of layers) the basal plane alignment of the film is degraded. Additionally, control of the temperature of the substrate adds additional ability to produce the well-ordered TMDs. Control of these parameters allows necessary adjustment of nucleation density and growth rates for minimization of atomic-scale defect formation in the materials to maximize effects observed for few-layer materials which are significantly different than bulk materials of the same composition. Control of temperature as well as charged particle (i.e., ions and electrons) flux allows exquisite control of nucleation and growth phenomena, which dictates the defect densities of continuous few-layer TMD films, and ultimately their electronic and optical properties. A narrow range of flux compositions resulting from power modulation in the substrate temperatures specified above give rise to the required low nucleation densities and high growth rates that are ideal for reducing the number of atomic-scale defects (primarily domain boundaries) in the materials. Materials made outside of this range of intrinsic processing parameters are generally randomly oriented or amorphous and do not have the atomic-scale ordering required for manifestation of the remarkable properties associated with few-layer TMD materials produced via other methods.

While the device of FIG. 1 described above has adjustable parameters via the magnetic field source 106, modulated power source 110, and heat source 114, a system with fixed parameters (permanent magnets, fixed pulse rate and duty factor, etc.) set to fixed parameters within the desired processing range could yield the same results.

The disclosed methods provide unmatched production of uniform and/or continuous, well-ordered films over large areas. In one embodiment, uniform and/or continuous growth of few-layer (one or more monolayers) of TMDs over a surface area of at least 1 cm² is achieved. In one embodiment, the surface area is at least 2 cm² and the growth of the TMD thereon is uniform and/or continuous over that surface area. In another embodiment, the surface area is at least 1 m² and the growth of the TMD thereon is uniform and/or continuous over that surface area. In all cases the substrate materials can be flexible or rigid, including continuous rolls of flexible materials.

The methods include providing a magnetically enhanced vapor deposition device 100 such as described above, placing a substrate in the substrate holder 112, activating the magnetic field source 106 to provide a magnetic field that controls a charged particle flux within the physical vapor deposition chamber 104, activating the modulated power source 110, and, optionally, activating the heat source 114. The methods may also include applying a vacuum to the physical vapor deposition chamber 104 and, subsequently, backfilling the physical vapor deposition chamber 104 with inert gas, a reactive gas, or a combination of inert and reactive gases.

The methods disclosed herein may be used to produce TMDs, in particular, TMDs grown on larger surface areas such that the material is useful in large area applications such as field effect transistors, light emitting diodes, and other electronic or spintronic devices, biological or molecular sensors, flexible electronics, hydrogen production via water splitting, diffusion barrier materials, thermoelectric and photovoltaic power generation and other technological applications. The physical vapor deposition process employed here can easily be integrated into traditional semiconductor processing fabrication systems as the primary tools are currently used in practice. The methods are environmentally safe with no toxic precursors or byproducts. The methods are also based on magnetron sputtering, and are therefore easily scalable to very large (1 m×1 m) areas.

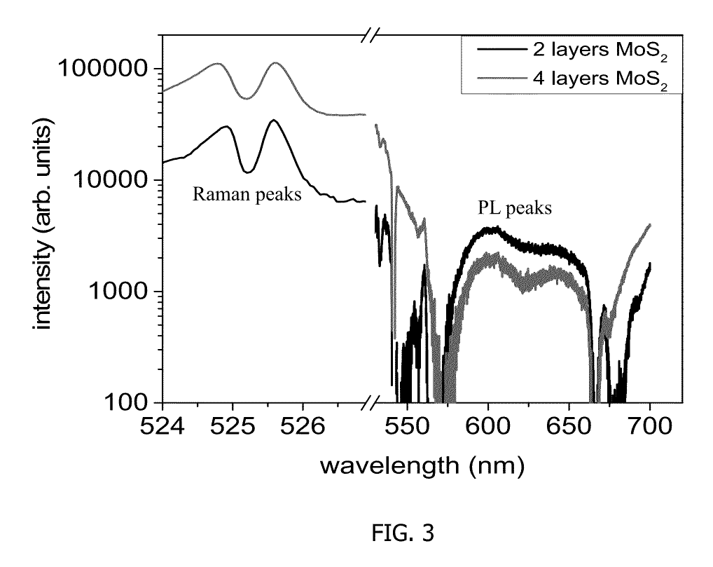

We have demonstrated the technology on the laboratory scale, examining the structure of few-layer TMDs via transmission electron microscopy as seen in FIG. 2A, Raman spectroscopy and, for semiconducting TMDs, photoluminescence spectroscopy. We have also measured intrinsic processing parameters resulting in highly ordered, few-layer TMD materials at moderate processing temperatures. We have also demonstrated thickness-dependent luminescence at the appropriate wavelengths, confirming the thickness and the high degree of atomic level order in semiconducting TMDs. FIG. 3 is a Raman spectra (524-527 nm, with higher intensity for thicker film) and thickness-dependent photoluminescence spectra (with higher intensity for thinner film) for MoS₂ samples produced in the range of power modulation, magnetic field, and temperature conditions presented here.

In one aspect, methods of magnetically enhanced physical vapor deposition is disclosed. The methods include providing a housing defining a physical vapor deposition chamber having a magnetic field source proximate a magnetron target that is coupled to a dc or modulated power source and a substrate holder that is coupled to a heat source, placing a substrate in the substrate holder; activating the magnetic field source to provide a magnetic field that controls a charged particle flux within the physical vapor deposition chamber; activating the modulated power source, and, optionally, activating the heat source. The methods may also include applying a vacuum to the physical vapor deposition chamber and, subsequently, backfilling the physical vapor deposition chamber with inert gas.

In one embodiment, the magnetron target includes a source of a transition metal dichalcogenide. The source of TMD can be a bulk material with the same composition as the desired few-layer TMD, which for example, may be molybdenum sulfide (MoS₂). Multiple sources with individual constituents of the TMD compound may also be used. The method deposits MoS₂ on the substrate as a continuous few-layer MoS₂. In one embodiment, the few-layer MoS₂ is continuous over a surface area of at least 1 cm². In another embodiment, the few-layer MoS₂ is continuous over a surface area of at least 2 cm².

In one embodiment, the magnetic field source is an adjustable magnetic field source, for example, a Helmholtz coil. In another embodiment, the magnetic field source is a permanent magnet. In one embodiment the magnetic field is directed parallel to the magnetron target and is at least strong enough to guide electrons present in the charged particle flux.

In one embodiment, the modulated power source operates in a frequency range of about 50 to about 85 kHz and a reverse time of about 0.4 to about 4 microseconds with a power density >1 Wcm².

In one embodiment, activating the heat source includes heating the substrate holder and hence the substrate to at least 200° C. The substrate may be silicon dioxide, highly oriented graphite, polycrystalline metal, polymer, or other materials provided they are chemically stable at the processing temperature and other conditions.

In one embodiment, the substrate may have a substrate area of about 1 mm² to about 1 m².

What is claimed is:

1. A method for magnetically enhanced physical vapor deposition, the method comprising:
providing a magnetically enhanced vapor deposition device defining a vapor deposition chamber, having a magnetic field source proximate a magnetron target that is positioned within the vapor deposition chamber and coupled to a power source, and having a substrate holder positioned within the vapor deposition chamber;
placing a substrate in the substrate holder;
activating the magnetic field source to provide a magnetic field that controls a charged particle flux within the physical vapor deposition chamber; and
activating the power source thereby depositing a few-layer film of the material comprising the magnetron target onto the substrate.

2. The method of claim 1, wherein the magnetically enhanced vapor deposition device further comprises a heat source coupled to the substrate holder to transfer heat thereto; and the method further comprises activating the heat source.

3. The method of claim 1, further comprising applying a vacuum to the vapor deposition chamber and, subsequently, backfilling the vapor deposition chamber with an inert gas, a reactive gas, or a combination thereof.

4. The method of claim 1, wherein the magnetron target includes a source of a transition metal dichalcogenide or a transition metal used in reactive gas to form a dichalcogenide.

5. The method of claim 4, wherein the transition metal dichalcogenide is a bulk material with the same composition as the few-layer film desired to be deposited on the substrate.

6. The method of claim 4, wherein the transition metal dichalcogenide includes molybdenum sulfide (MoS₂).

7. The method of claim 6, wherein the few-layer film comprises uniform and/or continuous layers of MoS₂.

8. The method of claim 1, wherein the few-layer film is uniform and/or continuous over a surface area of at least 1 cm².

9. The method of claim 1, wherein the few-layer film is uniform and/or continuous over a surface area of at least 2 cm².

10. The method of claim 1, wherein the magnetic field source is an adjustable magnetic field source.

11. The method of claim 10, wherein the adjustable magnetic field source is a Helmholtz coil.

12. The method of claim 1, wherein the magnetic field source is a permanent magnet.

13. The method of claim 1, wherein the magnetic field is directed parallel or has a generally parallel component relative to a primary surface of the magnetron target and is at least strong enough to guide electrons present in the vapor deposition chamber.

14. The method of claim 1, wherein the power source is a modulated power source that operates in a frequency range of about 50 to about 85 kHz and a reverse time of about 0.4 to about 4 microseconds with a power density >1 Wcm⁻².

15. The method of claim 2, wherein activating the heat source includes heating the substrate holder and hence the substrate to about 200° C.

16. The method of claim 1, wherein the substrate includes silicon dioxide, highly oriented graphite, polycrystalline metal, or a polymer that is chemically stable in the vapor deposition chamber during the method.

17. The method of claim 1, wherein the substrate has a substrate area of about 1 mm² to about 1 m².

18. A substrate having a few-layer film deposited thereon made according to the method of claim 1.
